(19) United States
(12) Patent Application Publication
(10) Pub. No.: US 2019/0025574 A1
(43) Pub. Date: Jan. 24, 2019

(54) Method for Designing Imaging Objective Lens System of Anamorphic Magnification

(71) Applicant: BEIJING INSTITUTE OF TECHNOLOGY, Beijing (CN)

(72) Inventors: Yanqiu LI, Beijing (CN); Yan LIU, Beijing (CN); Zhen CAO, Beijing (CN)

(21) Appl. No.: 16/140,869

(22) Filed: Sep. 25, 2018

Related U.S. Application Data
(63) Continuation of application No. PCT/CN2017/000223, filed on Mar. 9, 2017.

(30) Foreign Application Priority Data
Mar. 25, 2016 (CN) 201610178107.4

(51) Int. Cl. G02B 27/00; G02B 17/06; G03F 7/20

(52) U.S. Cl. CPC G02B 27/0012; G03F 7/7015; G02B 17/0652

(57) ABSTRACT

A method for designing an imaging objective lens system with an anamorphic magnification. The method includes the following steps: designing a coaxial overall spherical imaging objective lens system A with an M magnification; only using the curvatures of reflectors in the system A as optimization variables to optimize the system A into a system B with an N magnification; transforming the reflectors in the system A to have an anamorphic aspherical surface profile, wherein the longitudinal curvature of each anamorphic aspherical surface remains unchanged, and the transverse curvature is the curvature of the corresponding reflector in the system B; and obtaining an anamorphic magnification imaging system C with an M longitudinal magnification and an N transverse magnification. The imaging objective lens system designed with the method can realize different magnification in different directions.

### CROSS REFERENCE TO RELATED APPLICATIONS

This application is a continuation of International Patent Application PCT/CN2017/000223, filed Mar. 9, 2017, which claims priority to Chinese Patent Application 201610178107.4, filed Mar. 25, 2016. The disclosures of these prior-filed applications are incorporated by reference herein in their entirety.

### TECHNICAL FIELD

The present invention relates to a method for designing an imaging objective lens system with an anamorphic magnification, can be used in a step scan extreme ultraviolet lithography (EUVL) machine, a space imaging telescope, an imaging spectrometer or a micro-objective lens imaging system, and relates to the technical field of optical designs.

### BACKGROUND

EUVL has become a major lithography technique for realizing the 8-10 nm technology node in the semiconductor manufacturing industry. In order to satisfy the requirement, the numerical aperture of An EUVL objective lens needs to be greater than 0.45. Adopting the conventional ¼× magnification system to realize such a high numerical aperture would cause two phenomena: (1) the object plane incidence angle of chief rays at a central field-of-view is greater than 6 degrees; and (2) an incident beam and an outgoing beam at a mask are overlapped. The phenomenon (1) would cause a 3D shadow effect to the mask; and the phenomenon (2) would cause the objective lens system to fail to image properly. Therefore, the conventional ¼× magnification lithography objective lens cannot reasonably realize an ultrahigh numerical aperture.

In the prior art, US patent (U.S. Pat. No. 8,810,906B2) designs an EUVL objective lens with six free-form-surface reflectors, all the structures thereof have a ⅛ magnification. The structure can realize 0.5-0.7 ultrahigh numerical aperture, and can avoid the occurrence of the above-described two phenomena. However, due to the improvement of magnification, the area of a scanning exposure field-of-view is reduced by four times, while the sizes of the mask and a silicon wafer are unchangeable. Therefore, to image a six inch (133×102 mm²) mask, 4 exposure field-of-views are required to be spliced. This reduces production efficiency, and is unacceptable for the semiconductor industry.

### SUMMARY OF THE INVENTION

The object of the present invention is to provide a method for designing an imaging objective lens system with an anamorphic magnification (the magnification in the exposure scanning direction is M, and the magnification in a direction perpendicular to the scanning direction is N). The imaging objective lens system designed with the method can realize different magnifications in different directions.

The technical solution of the present invention is as follows:

A method for designing an imaging objective lens system with an anamorphic magnification, comprising:

Step 1, designing a coaxial overall spherical imaging objective lens system A with an M magnification;

Step 2, using the curvatures of reflectors in the system A as the optimization variables to optimize the system A into a system B with an N magnification; and

Step 3, transforming the reflectors in the system A to have an anamorphic aspherical surface profile, wherein the longitudinal curvature of each anamorphic aspherical surface remains unchanged, and the transverse curvature is the curvature of the corresponding reflector in the system B, thereby obtaining an anamorphic magnification imaging system C with an M longitudinal magnification and an N transverse magnification.

Further, the present invention further comprises: step 4, for the reflectors in the imaging system C, adding low order aspherical terms to perform optimization until the requirements for imaging performances are satisfied.

Further, the present invention further comprises: step 4, for the reflectors in the imaging system C, adding low order aspherical terms to perform optimization; and if adding low order aspherical terms to perform optimization cannot satisfy the imaging requirements, then using aspherical terms of higher order of the aspherical surfaces to perform further optimization until the requirements for imaging performances are satisfied.

Further, the present invention further comprises: step 4, for the reflectors in the imaging system C, adding low order aspherical terms to perform optimization; if adding low order aspherical terms (4-6 orders) to perform optimization cannot satisfy the imaging requirements, using higher order aspherical terms (8-10 orders) to perform further optimization; and if the imaging requirements still cannot be satisfied, fitting high order anamorphic aspherical surfaces into free-form surfaces to perform optimization until the requirements for imaging performances are satisfied.

### Beneficial Effects

First, the method directly obtains an initial structure of the imaging objective lens system with an anamorphic magnification by combining two coaxial overall spherical imaging objective lens systems. Therefore, the design efficiency is greatly improved.

Second, the method uses a coaxial overall spherical imaging objective lens systems to as a starting point, and can, by adjusting the structural parameters thereof (such as, optical distances between elements, incidence angles of light on each element, an object-image telecentricity and the like), indirectly control the various optical parameters of the initial structure of the imaging objective lens system with an anamorphic magnification. Therefore, the reasonableness of the initial structure of the system with an anamorphic magnification is improved.

Third, the present invention uses a progressive optimization approach to optimize the initial structure of the system with an anamorphic magnification, thereby avoiding dramatic departure of the optimized structure from the initial structure which may lead to an unreasonable structure, accelerating optimization convergence speed, and improving optimization efficiency.

### BRIEF DESCRIPTION OF THE DRAWINGS

FIG. 1 is a flow diagram of implementation of the design method in the detailed description of the embodiments;

FIG. 2 is a schematic view of an anamorphic aspherical surface in an embodiment in the detailed description of the embodiments;

FIG. 3 is a ⅛× coaxial rotationally-symmetrical lithography objective lens system in an embodiment in the detailed description of the embodiments;

FIG. 4 is the shapes of system pupils before and after being assembled in an embodiment in the detailed description of the embodiments;

FIG. 5 is a lithography objective lens system with an anamorphic magnification in an embodiment in the detailed description of the embodiments;

FIG. 6 is a mask, a silicon wafer and an exposure field-of-view in an embodiment in the detailed description of the embodiments;

FIG. 7 is a schematic view of a free-form surface in an embodiment in the detailed description of the embodiments;

FIG. 8 includes schematic views of reflectors M5 and M6 with central holes involved in an embodiment in the detailed description of the embodiments;

FIG. 9 is a schematic diagram of a diaphragm with a central obscuration in an embodiment in the detailed description of the embodiments;

FIG. 10 is a root mean square wave aberration distribution diagram of an objective lens in a full field-of-view in an embodiment in the detailed description of the embodiments; and

FIG. 11 is a two-dimensional distribution diagram of objective lens distortions in a full field-of-view involved in an embodiment in the detailed description of the embodiments.

### DETAILED DESCRIPTION OF THE EMBODIMENTS

The present invention will be elaborated hereafter in connection with the drawings and specific embodiments.

The design concept of the present invention is: using a grouping design method to design an overall spherical imaging system A with an M magnification, then changing only the curvature radius of each reflection element to transform the system A into a system B with an N magnification; combining the curvature radii of corresponding reflection elements of the systems A and B to obtain an initial structure of a system with an anamorphic magnification; then sequentially adding aspherical coefficients from low order to high order to optimize the initial structure; If the requirements for imaging performances cannot be satisfied, selecting certain reflection elements to fit the high order aspherical surfaces thereof into free-form surfaces with higher degrees of freedom, until the requirements for imaging performances are satisfied.

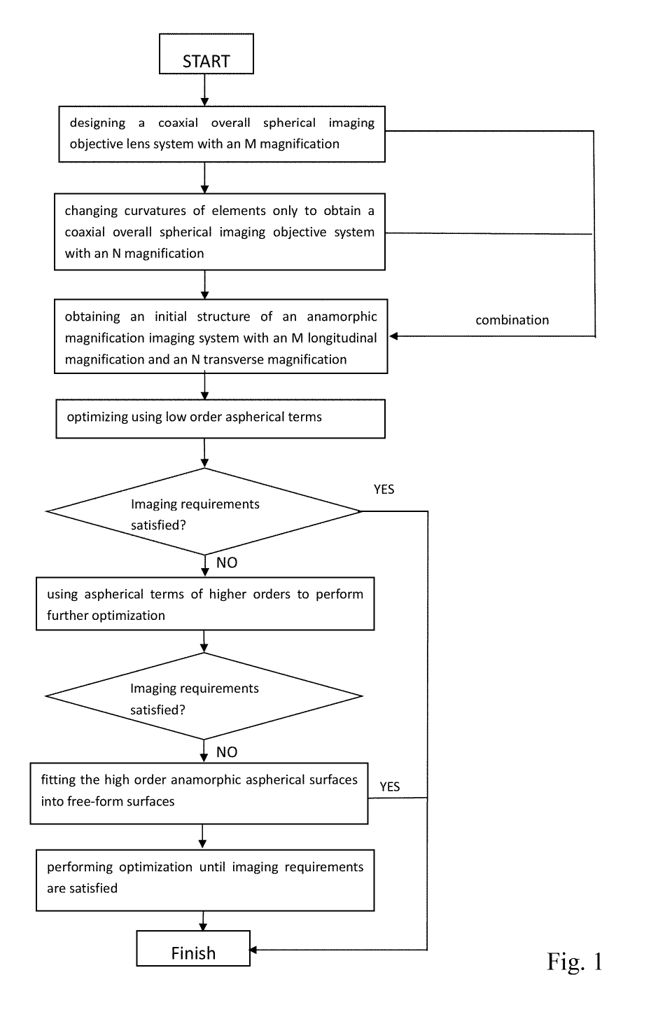

As shown in FIG. 1, the design process mainly comprises two parts: initial structure design and initial structure optimization; the design process is realized in optical design software.

Initial structure design: (1) based on basic characteristics of the required system, utilizing the grouping design method to design an initial structure A of a coaxial overall spherical extreme ultraviolet imaging system with an M magnification;

(2) using optical software to optimize the system into a system B with an N magnification, in which process only reflector curvatures are set as optimization variables, and the other variables remain unchanged;

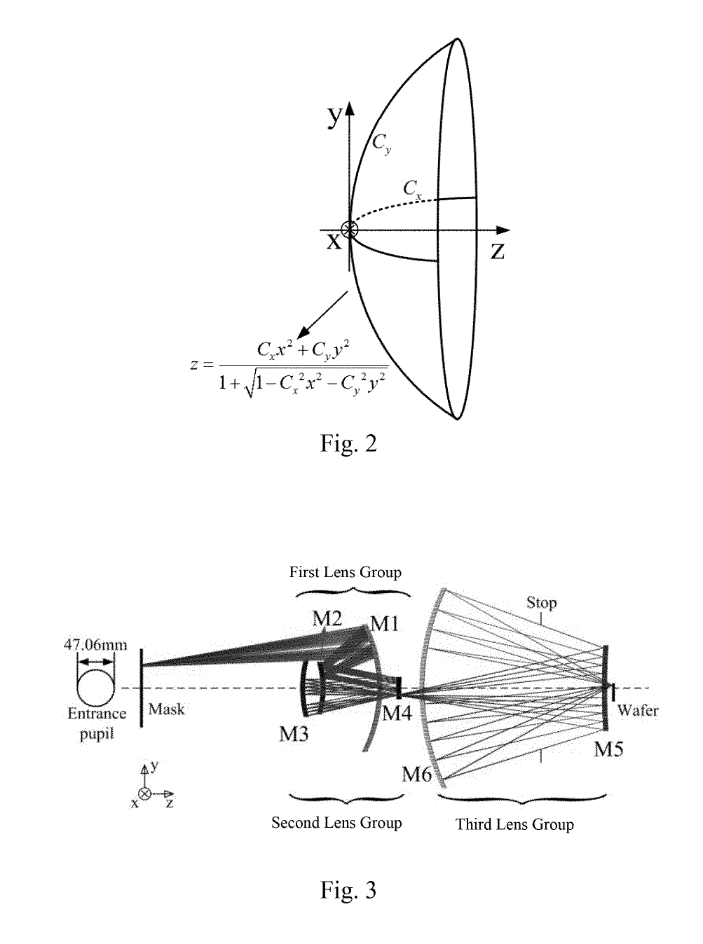

(3) transforming the spherical surface profiles of the reflectors in the system A into anamorphic aspherical surface profiles, wherein the transverse (X direction) curvature at the apex of the anamorphic aspherical surface is Cₓ, and the longitudinal (Y direction) curvature is C_{y}; as shown in FIG. 2, the reflectors in the system A are still rotationally-symmetrical spherical surfaces, in which case Cₓ=C_{y},

$$Z = \frac{{C}_{x}^{2} \cdot {X}^{2} + {C}_{y}^{2} \cdot {Y}^{2}}{1 + \sqrt{1 - {C}_{x}^{2} \cdot {X}^{2} - {C}_{y}^{2} \cdot {Y}^{2}}}$$

(4) replacing the transverse (X direction) curvatures of the reflectors in the system A with the curvatures of the reflectors in the system B, and keeping the longitudinal (Y direction) curvatures unchanged, thereby obtaining an initial structure of an anamorphic magnification imaging system with an M longitudinal magnification and an N transverse magnification.

Initial structure optimization: adding low order aspherical terms (4-6 orders) to the reflectors of the obtained objective lens system to perform optimization; if the initial structure can be optimized such that the requirements for imaging performances can be satisfied, the design is complete. If the performance requirements cannot satisfied by the above optimization, appropriate aspherical terms of higher orders (8-10 orders) are then used to perform further optimization. If the performance requirements still cannot be satisfied, then the high order anamorphic aspherical surfaces can be fitted into free-form surfaces having more free variables to perform optimization until the requirements for imaging performances are satisfied.

### Example

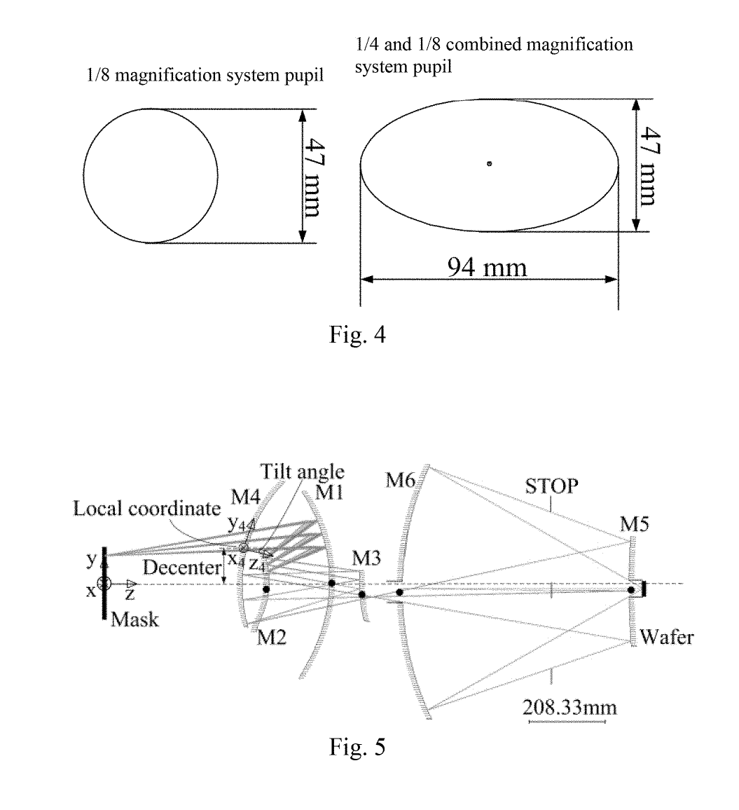

An extreme ultraviolet lithography objective lens with an anamorphic magnification is designed according to a specific embodiment. First, as shown in FIG. 3, a ⅛ magnification coaxial six-reflector system is used to start the design. The system is obtained with the grouping design method. Namely, the six reflectors are grouped pairwise. In the light path direction, the first reflector M1 and the second reflector M2 form a first reflector group G1; the third reflector M3 and the fourth reflector M4 form a second reflector group G2; the fifth reflector M5 and the sixth reflector M6 form a third reflector group G3. First, the reflector groups G1 and G3 are designed according a reasonable constraint condition, the intermediate reflector group G2 is determined according to an object-image relationship and a pupil matching principle, and an appropriate reflector group G2 is selected to couple with the reflector groups G1 and G3 to obtain the overall objective lens structure. Then, the original ⅛× system is transformed into a ¼× coaxial rotationally-symmetrical system by setting the curvatures of the reflectors as the only variables. Finally, the curvatures of corresponding reflectors of the two systems are combined to obtain the initial structure of an anamorphic aspherical objective lens system with an anamorphic magnification. In order to ensure system resolution, the system exit pupil must be circular. Due to the anamorphic magnification of the system, the entrance pupil is not in a circular shape, but in a elliptic shape with a 2:1 major-minor axis ratio as shown in FIG. 4. Therefore, an illumination system matched with the objective lens system should be modified to match the elliptic entrance pupil of the objective lens.

An asymmetrical magnification EUVL projection objective lens system is designed on the coaxial six-reflector system. As shown in FIG. 5, the EUVL projection objective lens system comprises an object plane, an image plane, reflectors M1-M6 and a circular diaphragm with a central obscuration. A global coordinate system is established by taking the visual field center of the object as the origin.

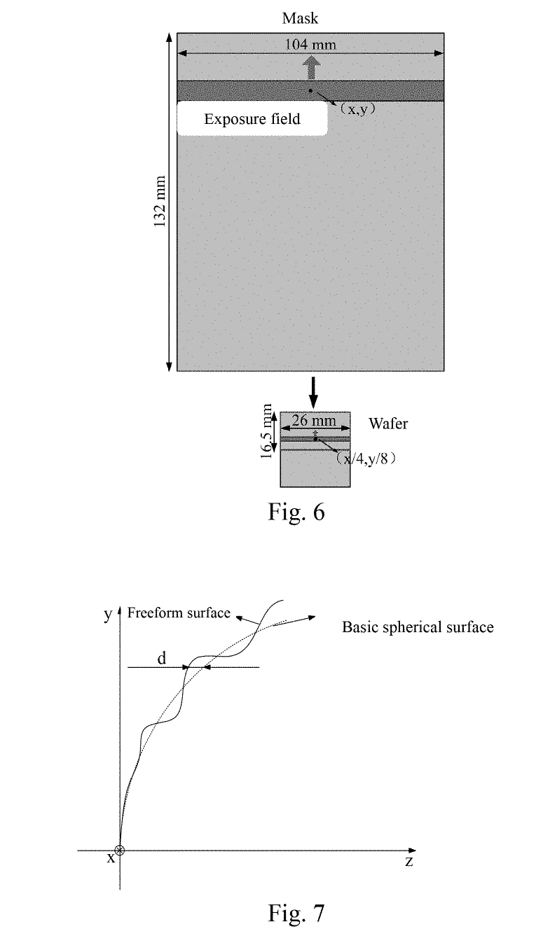

The exposure field-of-view of the objective lens on the mask and the silicon wafer is as shown in FIG. 6. The mask and the silicon wafer (an object plane and an image plane) are both planary, and are parallel with each other. The size of the mask is 102×132 mm²; and the illuminated object field-of-view is 102×2 mm². The mask is scanned and imaged in a fixed direction. The size of the silicon wafer is 26×33 mm²; and the scanning exposure field-of-view, which is 26×16.5 mm², is a half of the silicon wafer area. Therefore, the exposure field-of-view is required to be spliced only once.

The six reflectors all have free-form surfaces. FIG. 7 shows a sectional view of a typical free-form surface on a local axis YZ plane. Each free-form surface has a reference rotationally-symmetrical quadratic surface, on the basis of which a plurality of polynomials are added to control the offset of the free-form surface relative to the quadratic surface. The apex of the reference quadratic surface is the origin of a local coordinate system; the rotationally-symmetrical axis thereof is the optic axis, namely the Z axis of the local coordinate system.

The free-form surfaces of the objective lens system are all denoted with xy polynomials. By taking the local optic axis of each reflector as a Z axis, the free-form surface equation can be denoted as follows:

$$Z = \frac{{cr}^{2}}{1 + \sqrt{1 - ( 1 + k ) {c}^{2} {r}^{2}}} + {{\sum }_{j = 2}}^{66} {C}_{j} {X}^{m} {Y}^{n}$$

$$j = \frac{{( m + n )}^{2} + m + 3 n}{2} + 1$$

wherein r²=X²+Y², c is the apex curvature of the free-form surface, k is the coefficient of an aspherical surface, and Cⱼ is the coefficient of the polynomial XₘYₙ. In order to reduce surface profile complexity and improve optimization efficiency, the expressions of the free-form surfaces in the present invention only use even order terms of X, such that the system is still symmetrical on the meridian plane. The surface profile parameters of the six free-form-surface reflectors are as shown in Table 1.

TABLE 1
The surface profile parameters of the free-form-surface reflectors

| | M1 | M2 | M3 | M4 | M5 | M6. |
|---|---|---|---|---|---|---|
| c | −0.00197193 | −0.00469521 | 0.00181251 | 0.00262865 | 0.000420869 | 0.00122840 |
| K | 0.334904 | 0.0566781 | 0.157557 | −0.147927 | −0.615143 | 0.168331 |
| C3 | 0.0733058 | 0.135540 | −0.316147 | −0.00192083 | −0.0603169 | −0.00514696 |
| C4 | −0.000297411 | 0.378516e−4 | −0.000459146 | −0.00023951 | −0.122528e−4 | −0.366309e−5 |
| C6 | −0.000213452 | 0.000132113 | 0.000136621 | −0.457337e−4 | 0.108650e−4 | 0.144692e−5 |
| C8 | 0.27850e−6 | 0.205923e−5 | −0.189204e−5 | 0.231523e−6 | 0.251522e−7 | 0.861586e−9 |
| C10 | 0.935811e−7 | 0.205993e−5 | 0.132120e−5 | 0.216954e−6 | 0.653480e−7 | 0.178203e−8 |
| C11 | −0.395438e−9 | 0.282460e−7 | 0.135728e−7 | −0.2427143e−9 | 0.109918e−8 | −0.147615e−10 |
| C13 | −0.783518e−9 | −0.883414e−8 | 0.125900e−7 | 0.147049e−8 | 0.226163e−8 | −0.270435e−10 |
| C15 | 0.339682e−9 | −0.281710e−8 | 0.765885e−9 | −0.806154e−9 | 0.137111e−8 | −0.567773e−11 |
| C17 | −0.5o5889e−12 | −0.915677e−9 | −0.425807e−9 | 0.753748e−11 | 0.756500e−13 | 0.562323e−15 |
| C19 | 0.391463e−11 | 0.579465c−9 | −0.142020e−9 | 0.277201e−10 | 0.496945e−12 | 0.422918e−14 |
| C21 | 0.6775l9e−13 | 0.261132e−10 | 0.558038e−10 | −0.398646e−11 | 0.613641e−12 | 0.725458e−14 |
| C22 | −0.747999e−15 | 0.389797e−12 | −0.866065e−13 | 0.120928e−14 | 0.285563e−14 | −0.114407e−16 |
| C24 | 0.244897e−13 | 0.338553e−10 | 0.333202e−10 | 0.151026e−12 | 0.943514e−14 | −0.277578e−16 |
| C26 | −0.801096e−14 | 0.354311e−14 | 0.140735e−11 | 0.257747e−12 | 0.1170327e−13 | −0.962667e−17 |
| C28 | 0.106619e−14 | 0.210455e−11 | −0.241942e−11 | 0.234927e−13 | 0.126142e−14 | −0.165801e−16 |
| C30 | −0.184708−16 | −0.180306e−13 | 0.119092e−13 | 0.802098e−16 | 0.421413e−18 | 0.901867e−23 |
| C32 | −0.224328e−15 | −0.644117e−12 | −0.133159e−11 | 0.1754454e−14 | 0.382315e−17 | 0.639448e−20 |
| C34 | −0.748316e−16 | −0.829766e−13 | 0.266343e−12 | 0.165236e−14 | 0.737813e−17 | 0.171719e−19 |
| C36 | 0.223391e−16 | −0.149014c−13 | 0.146946e−13 | 0.132475e−15 | −0.285246e−17 | −0.205917e−20 |
| C37 | −0.626417e−20 | O.410999c−17 | −0.535034e−16 | −0.171496e−19 | 0.120680e−19 | −0.101038e−22 |
| C39 | 0.259366e−18 | 0.432340e−15 | 0.510023e−15 | 0.797427e−18 | 0.603780e−19 | −0.290416e−22 |
| C41 | 0.100953e−17 | 0.689779e−14 | 0.267475e−13 | 0.107704e−16 | 0.118251e−18 | −0.690498e−23 |
| C43 | 0.787264e−18 | 0.92292.3e−15 | −0.837146e−14 | 0.709407e−17 | 0.359271e−19 | −0.355012e−22 |
| (:45 | 0.326014e−19 | 0.642988e−16 | 0.184958e−14 | −0.278000e−18 | 0.247792e−19 | 0.105861e−22 |
| C47 | 0.127490−22 | −0.103037e−18 | 0.310422e−17 | −0.296627e−21 | 0.601146e−23 | 0.948263e−27 |
| C49 | −0.141318e−20 | −0.426526e−17 | −0.194239e−16 | 0.375758e−20 | 0.701599e−22 | 0.257104e−25 |
| C51 | −0.197191e−20 | −0.387936e−16 | −0.261916e−15 | 0.342893e−19 | 0.514153e−22 | 0.455502e−25 |
| C53 | −0.243958e−20 | −0.342559e−17 | 0.100348e−15 | 0.187373e−19 | −0.401326e−22 | 0.9590266−26 |
| C55 | −0.722213e−21 | −0.714414e−18 | −0.265752e−16 | −0.219529e−20 | 0.259978e−23 | 0.522665e−26 |
| C56 | −0.290775e−25 | 0.170178e−21 | 0.149817e−20 | −0.225785e−24 | 0.983385e−25 | −0.111820e−28 |
| CSS | 0.270907e−25 | 0.119136e−20 | −0.565919e−19 | −0.157035e−23 | 0.646212e−24 | −0.337213e−29 |
| C60 | 0.292649e−23 | 0.162794e−19 | 0.162738e−18 | 0.577230e−23 | 0.115296e−23 | 0.582778e−28 |
| C62 | 0.127255e−23 | 0.905548e−19 | 0.992901e−18 | 0.436066e−22 | 0.545087e−24 | −0.893652e−29 |
| C64 | 0.275222e−23 | 0.280149e−20 | −0.435148e−18 | 0.222361e−22 | 0.631401e−24 | 0.522129e−28 |
| C66 | 0.211935e−23 | 0.346348e−20 | 0.116644e−18 | −0.254810e−23 | 0.126417e−25 | −0.107723e−28 |

In order to reduce system complexity and difficulty in debugging, the reflectors are eccentric and rotary only in the meridian plane. Table 2 shows the positions, eccentric amounts, and rotation angles of the reflectors, the object plane and the image plane. The terminologies are defined as follows: interval: the interval value is positive from left to right, and negative going the opposite direction; eccentricity: the eccentricity is positive in the positive direction of the global Y axis, and negative going the opposite direction; rotation angle: the rotation angle is positive when rotating counter-clockwise around the local X axis, and negative rotating the opposite direction.

TABLE 2
The relative positions and rotation angles between the elements

| Surface name | Distance/mm | Y-decenter/mm | X-rotation |
|---|---|---|---|
| Object plane | 616.9878 | 0 | 0 |
| M1 | −167.4646 | 0 | 3.3145 |
| M2 | 249.6118 | −19.3643 | 1.8512 |
| M3 | −330.0946 | −32.1529 | −12.3648 |
| M4 | 1043.6149 | 92.1326 | −14.0007 |
| M5 | −407.1389 | −21.5989 | −3.0117 |
| Stop | −213.4188 | −18.4830 | 0.1749 |
| M6 | 660.0917 | −23.4937 | 0.0875 |
| Image plane | | −23.4937 | 0 |

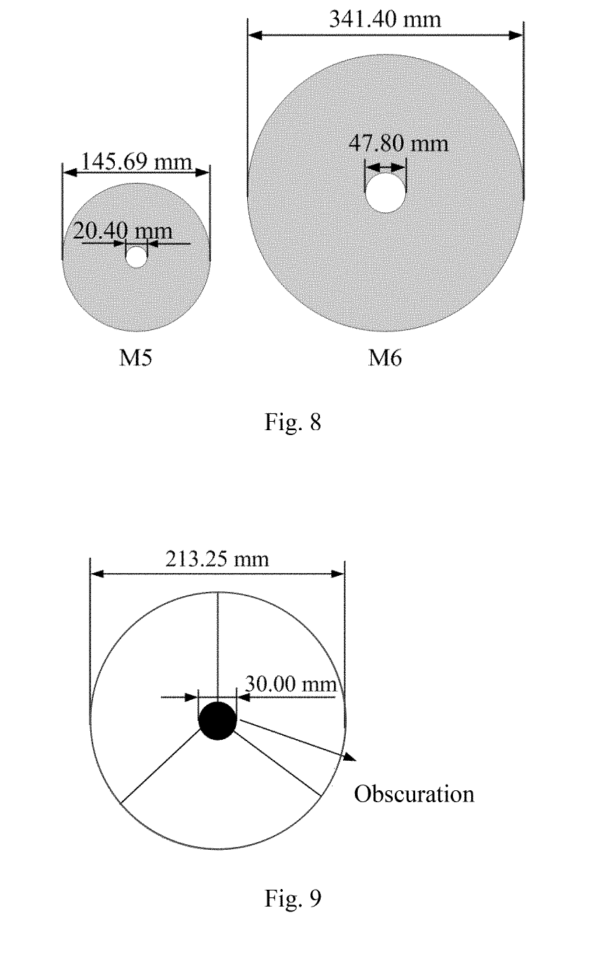

In order to reduce the incidence angle on the reflector M5, a central obscuration design method is adopted. As shown in FIG. 8, holes are drilled in the centers of the reflectors M5 and M6 to ensure the light to smoothly pass and be imaged on the image plane. Due to the holes, a part of the light cannot be reflected and imaged by M5 and M6. Therefore, such part of light must be covered to avoid from interfering with normal imaging. As shown in FIG. 9, a system diaphragm provided with a light shielding plate is used to realize the light coverage purpose.

The operating process of the EUVL projection objective lens of the present invention:

The light emitted by the illumination system is first reflected by the mask to the first reflector M1, then reflected by the first reflector M1 to the second reflector M2, then reflected by the third reflector M3 and the fourth reflector M4, and finally forms an intermediate image in proximity to the center of the sixth reflector M6. The chief rays of the fields-of-view are reflected out perpendicular to the image plane (image telecentricity), and are finally imaged on the image plane, namely on the silicon wafer plane. After being implemented according to the embodiment, the performance parameters of the EUVL objective lens are as shown in Table 3.

TABLE 3
The basic performance parameters of the EUVL objective

| | |
|---|---|
| Image numerical aperture | 0.5 |
| Operating wavelength/λ | 13.5 |
| Image exposure field-of-view/mm² | 16.5 × 33 |
| Magnification | Mx1/4, My1/8 |
| Total system length | 1476.46 mm |
| Incidence angle of chief ray of the | 16.93° |
| central field-of-view | |
| Chief rays of object central | 5.68° |
| field-of-view | |
| Incidence angle (CRAO) | |
| Image telecentricity | <1 mrad |
| Mixed wavefront aberration root | 0.05λ |
| mean square | |
| Distortion | <2.8 nm |

The total system length (the distance from the object plane to the image plane) is 1476.46 mm which is a reasonable length for a lithography object plane system. The image telecentricity is less than 1 mrad, ensuring that the magnification of the objective lens remains unchanged when the image plane has a minor axial movement. When the chief ray angle of object central field-of-view is 5.68 degrees, the numerical aperture reaches 0.5 which can realize the technical node 8-10 nm by combining a resolution enhancement technology. As shown in FIG. 2, the asymmetrical reduction ratio can realize the scanning exposure of half a silicon wafer, thus improving production efficiency.

The EUVL objective lens with an anamorphic magnification in the embodiment can be evaluated with the following two evaluation indicators:

1. Root Mean Square Wavefront Aberration

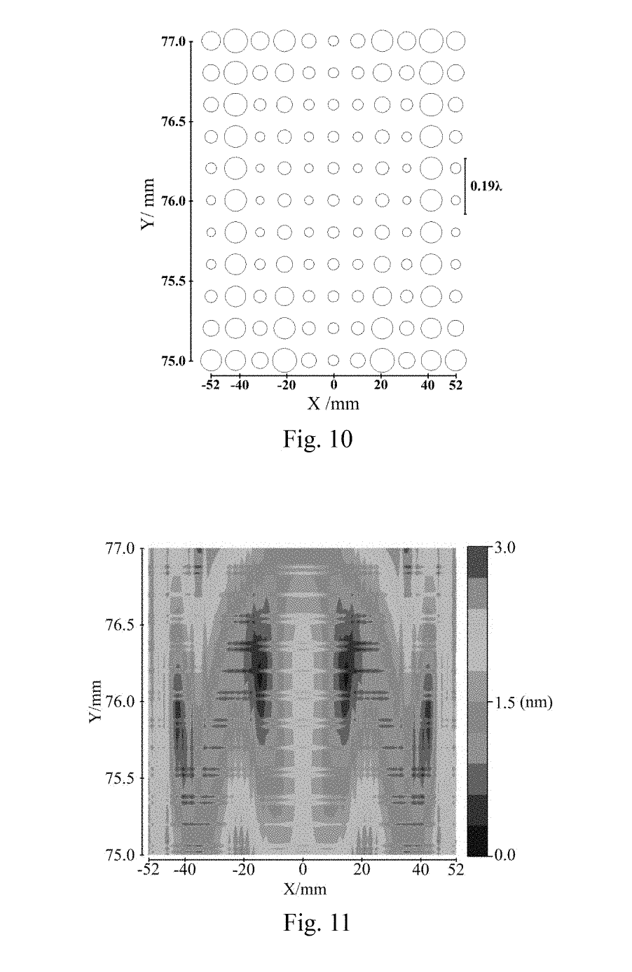

Root mean square wavefront aberration is an important indicator reflecting the imaging performances of an optical system. FIG. 10 is a two-dimensional root mean square wave aberration distribution diagram in a full field-of-view. The full field-of-view wave aberration RMS is less than lnm; and the full field-of-view average wave aberration RMS is 0.67 nm.

2. Distortion

Distortion is an important factor influencing the lithography performance of a system. And for a non-rotationally-symmetrical system, the distortion is required to be controlled by uniformly sampling points in the full field-of-view. FIG. 11 shows a two-dimensional distortion distribution diagram in the full field-of-view. As shown in the FIG. 11, the distortions of the field-of-view points on the object plane are all less than 2.8 nm.

The EUVL projection objective lens of the present invention has an excellent image quality, and has the potential of further improving the numerical aperture.

Although specific embodiments of the present invention are described in connection with the drawings; a person skilled in the art could make various alterations, substitutions and improvements without departing from the present invention. These alterations, substitutions and improvements are all encompassed in the protection scope of the present invention.

1. A method for designing an imaging objective lens system with an anamorphic magnification, characterized by, specifically comprising:
designing a coaxial overall spherical imaging objective lens system A with an M magnification;
using the curvatures of reflectors in the system A as optimization variables to optimize the system A into a system B with an N magnification; and
transforming each of the reflectors in the system A to have an anamorphic aspherical surface profile, wherein the longitudinal curvature of each anamorphic aspherical surface remains unchanged, and the transverse curvature is the curvature of the corresponding reflector in the system B, thereby obtaining an anamorphic magnification imaging system C with an M longitudinal magnification and an N transverse magnification.

2. The method for designing an imaging objective lens system with an anamorphic magnification according to claim 1, further comprising:
for the reflectors in the imaging system C, adding low order aspherical terms to perform optimization until requirements for imaging performances are satisfied.

3. The method for designing an imaging objective lens system with an anamorphic magnification according to claim 1, further comprising:
for the reflectors in the imaging system C, adding low order aspherical terms to perform optimization; and
if adding low order aspherical terms to perform optimization cannot satisfy the imaging requirements, then using aspherical terms of higher orders of the aspherical surfaces to perform further optimization until the requirements for imaging performances are satisfied.

4. The method for designing an imaging objective lens system with an anamorphic magnification according to claim 1, comprising:
for the reflectors in the imaging system C, adding low order aspherical terms to perform optimization;
if adding low order aspherical terms to perform optimization cannot satisfy imaging requirements, then using aspherical terms of higher orders of the aspherical surfaces to perform further optimization; and
if the imaging requirements still cannot be satisfied, then fitting the high order anamorphic aspherical surfaces into free-form surfaces to perform optimization until the requirements for imaging performances are satisfied.
